(19) United States
(12) Patent Application Publication
(10) Pub. No.: US 2015/0016863 A1
(43) Pub. Date: Jan. 15, 2015

(54) MOUNTING APPARATUS FOR SCREEN

(71) Applicant: HON HAI PRECISION INDUSTRY CO., LTD., New Taipei (TW)

(72) Inventor: YUN-LUNG CHEN, New Taipei (TW)

(21) Appl. No.: 14/326,680

(22) Filed: Jul. 9, 2014

(30) Foreign Application Priority Data
Jul. 11, 2013 (CN) 2013102897981

(51) Int. Cl. H05K 5/02

(52) U.S. Cl. CPC H05K 5/0221
USPC 403/13

(57) ABSTRACT

A mounting apparatus is used to secure a screen to a vending machine. The mounting apparatus includes a front plate defining an opening. The front plate includes a support piece protruding from an edge of the opening. A number of connecting members is mounted on the front plate. The support piece supports the screen thereon. The connecting members retain the screen on the front plate and align the screen with the opening.

### FIELD

The subject matter herein generally relates to a mounting apparatus for securing a screen on a vending machine.

### BACKGROUND

A screen may be mounted on a vending machine. A mounting apparatus is used to secure the screen to the vending machine.

### BRIEF DESCRIPTION OF THE DRAWINGS

Implementations of the present technology will now be described, by way of example only, with reference to the attached figures, wherein:

FIG. 1 is an exploded, isometric view of an embodiment of a mounting apparatus for securing a screen on a vending machine.

FIG. 2 is an isometric view of a support piece of FIG. 1.

FIG. 3 is a partially assembled isometric view of the mounting apparatus of FIG. 1.

FIG. 4 is an assembled isometric view of the mounting apparatus of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “outside” refers to a region that is beyond the outermost confines of a physical object. The term “inside” indicates that at least a portion of a region is partially contained within a boundary formed by the object. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

The present disclosure is described in relation to a mounting apparatus for securing a screen on a vending machine.

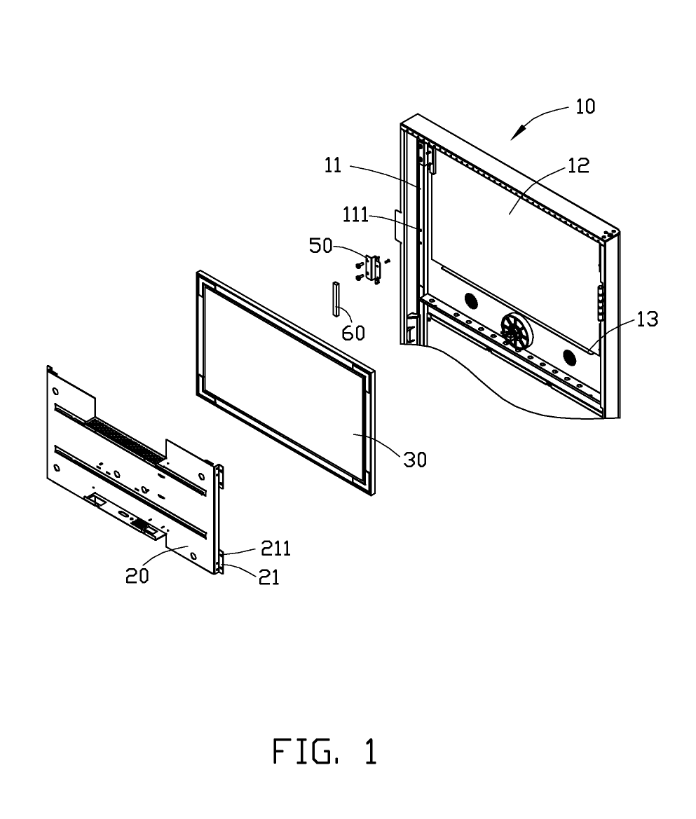

FIG. 1 illustrates a mounting apparatus in a vending machine is configured to secure a screen 30 to the vending machine and comprises a front plate 10 and a cover 20.

The front plate 10 comprises a plurality of posts 11. The posts 11 are substantially parallel to each other. An opening 12 is defined in the front plate 10 between the couple of the posts 11. A length of the screen 30 is greater than a length of the opening 12. A width of the screen 30 is greater than a width of the opening 12. Each post 11 defines a plurality of first securing holes 111. A support piece 13 protrudes from an edge of the opening 12 of the front plate 10. The support piece 13 can be formed by stamping.

An extending piece 21 protrudes from each of four corner portions of the cover 20. Each extending piece 21 defines a plurality of first locking holes 211.

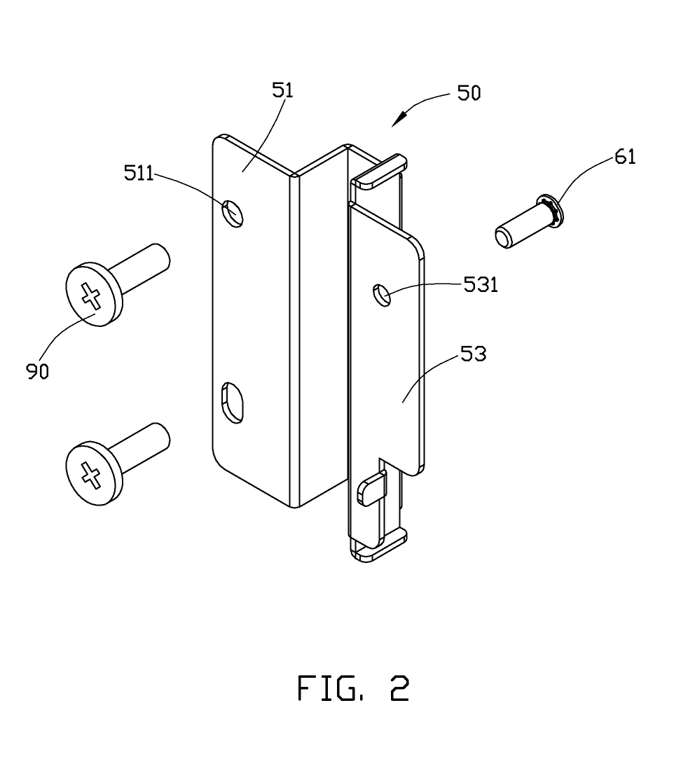

FIGS. 1-2 illustrate a plurality of connecting members 50 is secured to the posts 11. Each connecting member 50 comprises a first securing piece 51 and a second securing piece 53 substantially parallel to the first securing piece 51. Each first securing piece 51 and each second securing piece 53 are substantially parallel to the screen 30. Each first securing piece 51 defines a plurality of second securing holes 511 corresponding to the first securing holes 111 of a corresponding post 11. Each second securing piece 53 defines a second locking hole 531 corresponding to a corresponding first locking hole 211 of the cover 20. The mounting apparatus further includes a plurality of buffer members 60. Each buffer member 60 is made of a resiliently deformable and flexible material, such as sponge.

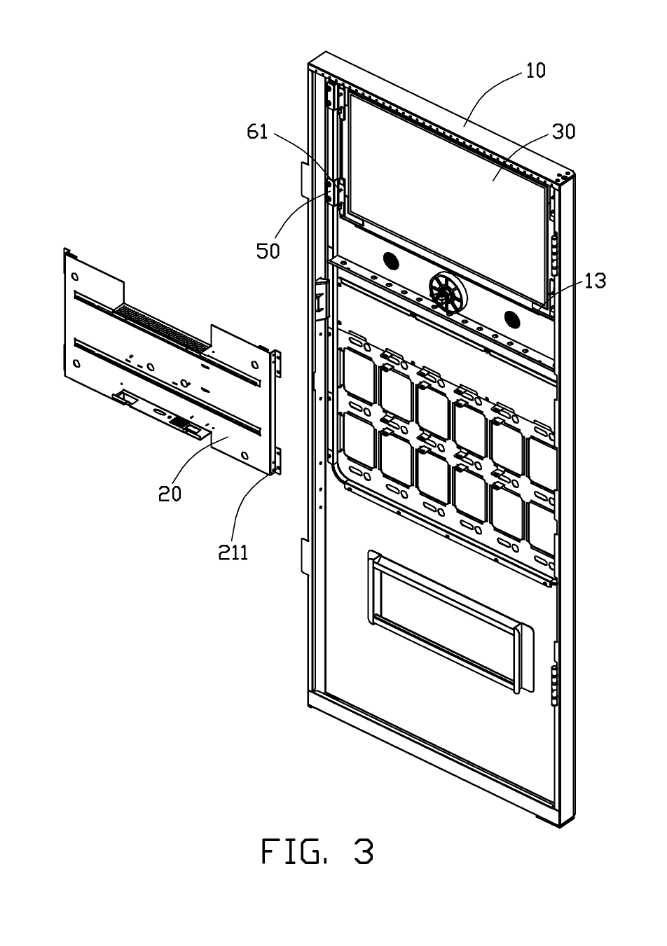

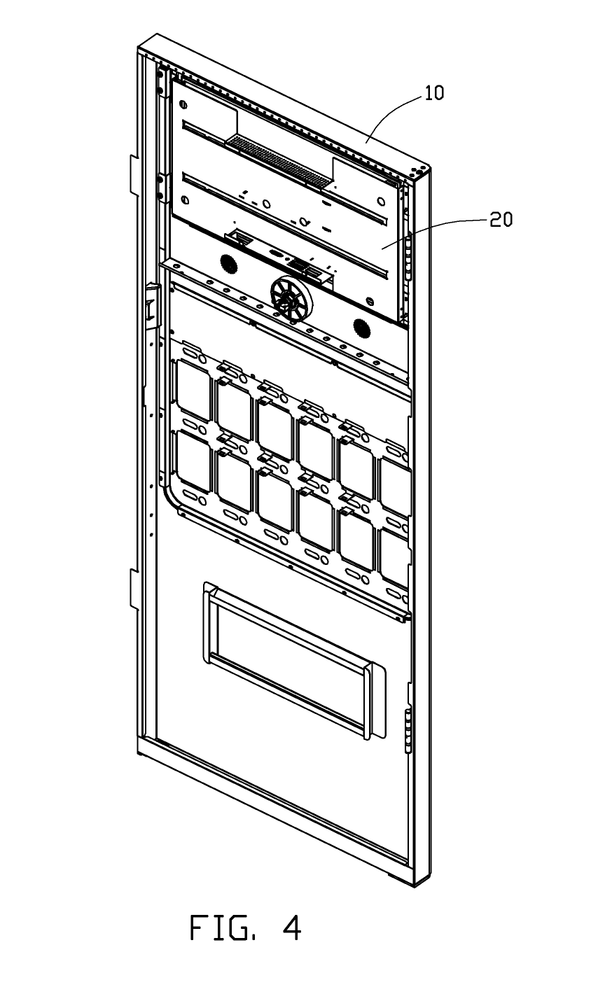

FIGS. 1-4 illustrate that in assembly, the screen 30 is aligned with the opening 12 of the front plate 10. A bottom edge of the screen 30 is placed on the support piece 13 of the front plate 10.

The second securing holes 511 of each connecting member 50 are aligned with the first securing holes 111 of the corresponding first post 11. A buffer member 60 is compressed between the second securing piece 53 of the corresponding connecting member 50 and the screen 30. A plurality of screws 90 extends through the corresponding first securing holes 111 and the corresponding second securing holes 511, thus fixing the connecting members 50 to the first posts 11. The second securing pieces 53 of the connecting members 50 press the screen 30 against the front plate 10 through the buffer member 60. The buffer members 60 buffer the screen 30 from external impact.

A back side of the screen 30 is covered by the cover 20. The first locking holes 211 of the cover 20 are aligned with the corresponding second locking holes 531 of the connecting member 50. A plurality of fasteners 61 extends through the first locking holes 211 and the second locking holes 531, so that the cover 20 is secured to the front plate 10. The cover 20 protects the screen 30.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A mounting apparatus for securing a screen in a vending machine comprising:
a front plate defining an opening for revealing a screen, the front plate comprises a support piece configured for supporting the screen, the support piece being located below the opening; and
a connecting member configured for retaining the screen on the front plate and aligning the screen with the opening, the connecting member being mounted on the front plate.

2. The mounting apparatus of claim 1, wherein the front plate defines a first securing hole, the connecting member comprises a first securing piece, the first securing piece defines a second securing hole, a screw is fixed to the first securing hole and the second securing hole, thereby mounting the connecting member to the front plate.

3. The mounting apparatus of claim 1, wherein the connecting member comprises a second securing piece, a buffer member is pressed between the second securing piece and the screen.

4. The mounting apparatus of claim 1, further comprising a cover, wherein the cover is located on a back of the screen.

5. The mounting apparatus of claim 4, wherein the cover defines a first locking hole, the connecting member further comprises a second securing piece, the second securing piece defines a second securing hole, a fastener is secured to the first securing hole and the second securing hole, thereby the cover is secured to the front plate.

6. The mounting apparatus of claim 1, wherein the connecting member comprises a first securing piece securing the connecting member to the front plate and a second securing piece secured to the front plate.

7. The mounting apparatus of claim 6, wherein the first securing piece is parallel to the second securing piece.

8. The mounting apparatus of claim 1, wherein a width of the screen is greater than a width of the opening.

9. The mounting apparatus of claim 1, wherein the front plate comprises a plurality of posts parallel to each other; the opening is defined between the plurality of the posts.

10. The mounting apparatus of claim 9, wherein a length of the screen is greater than that of the opening.

11. A mounting apparatus comprising:
a front plate defining an opening for revealing a screen, the front plate comprises a support piece configured for supporting the screen, the support piece being located below the opening;
a cover on a back of a screen for protecting the screen; and
a plurality of connecting members mounted on the front plate a connecting member is configured for retaining the screen on the front plate and aligning the screen with the opening.

12. The mounting apparatus of claim 11, wherein the front plate defines a plurality of first securing holes; each connecting member comprises a first securing piece; each first securing piece defines a second securing hole; each screw is fixed to each first securing hole and each second securing hole, thereby mounting each connecting member to the front plate.

13. The mounting apparatus of claim 12, wherein each connecting member further comprises a second securing piece, each buffer member is pressed between each second securing piece and the screen.

14. The mounting apparatus of claim 13, wherein each first securing piece is parallel to each second securing piece.

15. The mounting apparatus of claim 11, wherein each first securing piece is parallel to the screen.

16. The mounting apparatus of claim 11, wherein the cover defines a plurality of first locking holes; each connecting member further comprises a second securing piece; each second securing piece defines a second securing hole; each fastener is secured to each first securing hole and each second securing hole, thereby the cover is mounted to the front plate.

17. The mounting apparatus of claim 11, wherein a width of the screen is greater than a width of the opening.

18. The mounting apparatus of claim 11, wherein a length of the screen is greater than that of the opening.

19. The mounting apparatus of claim 11, wherein the front plate comprises a plurality of posts parallel to each other; the opening is defined between the plurality of the posts.
